(19) United States
(12) Patent Application Publication
(10) Pub. No.: US 2025/0279329 A1
(43) Pub. Date: Sep. 4, 2025

(54) SEMICONDUCTOR MODULE

(71) Applicant: HITACHI ASTEMO, LTD., Hitachinaka-shi, Ibaraki (JP)

(72) Inventors: Takahiro ARAKI, Tokyo (JP); Takeshi TOKUYAMA, Tokyo (JP); Shigehisa AOYAGI, Hitachinaka-shi (JP)

(73) Assignee: HITACHI ASTEMO, LTD., Hitachinaka-shi, Ibaraki (JP)

(21) Appl. No.: 18/702,558

(22) PCT Filed: Oct. 19, 2022
(86) PCT No.: PCT/JP2022/038966

§ 371 Date: Apr. 18, 2024

(30) Foreign Application Priority Data
Oct. 26, 2021 (JP) 2021-175054

(51) Int. Cl. H01L 23/367; H01L 23/18

(52) U.S. Cl. CPC H01L 23/3675; H01L 23/18

(57) ABSTRACT

A semiconductor module includes: a circuit body having a semiconductor element, and a plurality of external terminals to be connected to the semiconductor element; a substrate having a power wiring layer to be connected to the external terminals; an insulating filling member for covering a connection part between the external terminals and the power wiring layer; a cooler having one surface side on which the circuit body and the substrate are mounted; and a heat dissipation member disposed between the cooler and the substrate. In the semiconductor module, the heat dissipation member forms a frame part on the cooler so as to enclose an outer periphery of a region where the circuit body is mounted, and the filling member is filled into an inner peripheral side of the frame part.

### TECHNICAL FIELD

This invention relates to a semiconductor module.

### BACKGROUND ART

As the background art of the present invention, the following Patent Literature 1 discloses a configuration in which in the substrate for power module and the power module, the heat dissipation member is disposed over the whole surface.

### CITATION LIST

### Patent Literature

Patent Literature 1: Japanese Patent No. 6481409

### SUMMARY OF INVENTION

### Technical Problem

In view of enhancement of the substrate cooling performance for larger current, and individual power module packaging for productivity improvement, the technology disclosed in the Patent Literature 1 has difficulty in simultaneous cooling of the semiconductor module and the substrate because of different height. Furthermore, the use of insulation coating capable of spray coating makes it difficult to attain increase in the film thickness (high breakdown strength) owing to low viscosity. This causes the problem of difficulty in arrangement of the potting mold for filling the insulation coating onto the lower surface side of the substrate. In light of the problem as described above, it is an object of the present invention to provide the semiconductor module which attains both enhancement of cooling performance of the substrate, and high density of a terminal wiring.

### Solution to Problem

A semiconductor module of the present invention includes: a circuit body having a semiconductor element, and a plurality of external terminals to be connected to the semiconductor element; a substrate having a power wiring layer to be connected to the external terminals; an insulating filling member for covering a connection part between the external terminals and the power wiring layer; a cooler having one surface side on which the circuit body and the substrate are mounted; and a heat dissipation member disposed between the cooler and the substrate. In the semiconductor module, the heat dissipation member forms a frame part on the cooler so as to enclose an outer periphery of a region where the circuit body is mounted, and the filling member is filled into an inner peripheral side of the frame part.

### Advantageous Effects of Invention

It is possible to provide a semiconductor module which attains both enhancement of cooling performance of the substrate and high density of a terminal wiring.

### BRIEF DESCRIPTION OF DRAWINGS

FIG. 1 is an overall view of a substrate integrated type semiconductor module when seen from the top.

FIG. 2 is a sectional view taken along line A-A′ of FIG. 1.

FIG. 3 is a sectional view taken along line B-B′ of FIG. 1.

FIG. 4 represents a first modification of an example as shown in FIG. 3.

FIG. 5 represents a second modification of an example as shown in FIG. 3.

FIG. 6 represents a third modification of an example as shown in FIG. 3.

### ONE EMBODIMENT AND OVERALL STRUCTURE OF THE PRESENT INVENTION

Referring to the drawings, an embodiment of the present invention is described. The following description and drawings are mere examples for explaining the present invention, which may be omitted and simplified appropriately for clarifying the description. The present invention may be implemented in various forms. It is possible to use either single or multiple units of the respective components unless otherwise specified.

Data on positions, sizes, shapes, ranges of the respective components illustrated in the drawings do not necessarily reflect actual positions, sizes, shapes, ranges of those components. The present invention, therefore, is not necessarily limited to the positions, sizes, shapes, ranges as disclosed in the drawings.

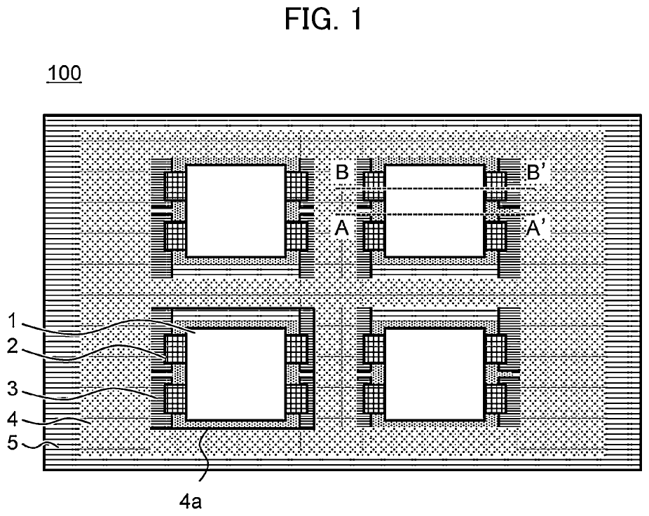

### (FIG. 1)

A substrate integrated type semiconductor module 100 is a circuit module constituting a power conversion circuit for a power converter. The semiconductor module 100 includes a circuit body 1, a power wiring layer 3, a heat dissipation member 4, and a substrate 5. The substrate 5 is a resin printed circuit board (control circuit board). The heat dissipation member 4 is formed to be a sheet-like shape onto the substrate 5, and is arranged so as to enclose the respective substrate bodies 1. The power wiring layer 3 is connected to the circuit body 1 via an external terminal 2 of each of the circuit bodies 1.

The reason why the heat dissipation member 4 is sheet-like shape is that a large number of heat dissipation members 4 are required in accordance with the current amount of a main circuit part of the power converter. As described later in detail, a large number of the heat dissipation members 4 form a frame part 4a around the circuit body 1 and the external terminals 2 of the circuit body 1, thereby to prevent leakage of a filling member to be filled around the circuit body 1.

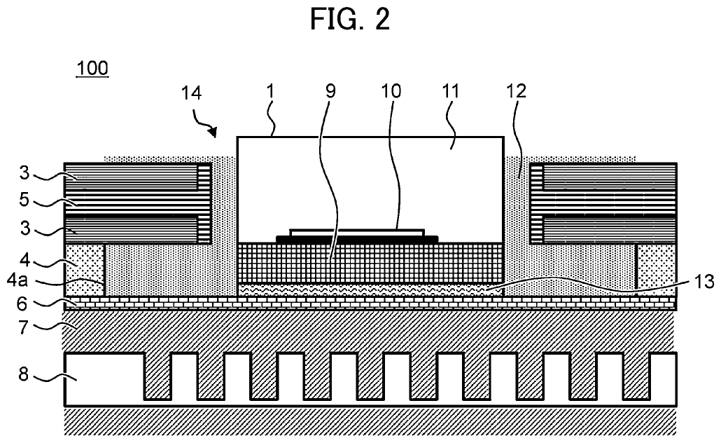

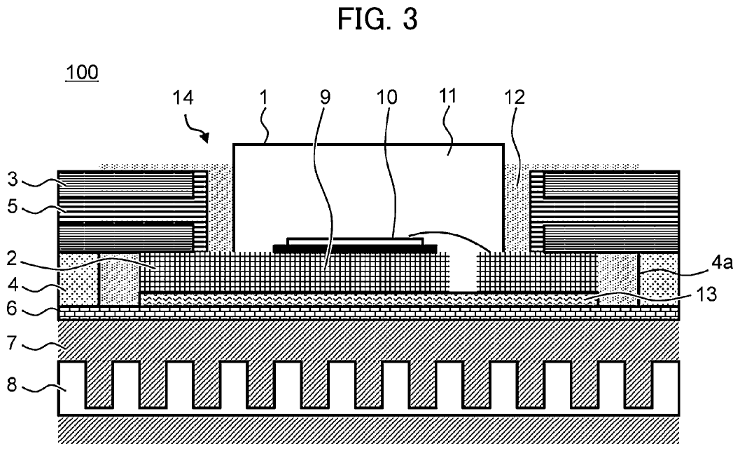

### (FIG. 2, FIG. 3)

The power wiring layer 3 is formed on both upper and lower surfaces of the substrate 5. The circuit body 1 is placed at an inner peripheral side of a through hole 14 formed in the substrate 5. The circuit body 1 has its side surfaces fixed to the substrate 5 via an insulating filling member 12 to improve vibration proofness. The circuit body 1 includes a conductive member 9 and a semiconductor element 10, each of which are sealed with a sealing resin 11. This allows the semiconductor element 10 and the conductive member 9 to be insulated against surrounding electrical components, and protected from foreign substances.

An IGBT (Insulated Gate Bipolar Transistor) element, a MOSFET (metal-oxide-semiconductor field-effect transistor) element, and a diode element may be used for forming the semiconductor element 10. The semiconductor element 10 is electrically connected to the conductive member 9 via a connecting wiring such as a bonding wire, and a bonding material such as a solder.

The conductive member 9 includes the external terminals 2 for connecting the circuit body 1 to such electrical component as the substrate 5. The external terminal 2 is connected to the semiconductor element 10, and electrically connected to the power wiring layer 3 (the lower side as shown in the drawing) of the substrate 5 by the bonding material such as the solder. The substrate 5 is constituted by the power wiring layers 3 and an insulating resin layer. The circuit body 1 is connected to not shown other electrical parts via the external terminals 2 and the substrate 5, to constitute the power conversion circuit.

By the through hole 14 formed in the substrate 5, the filling member 12 is filled so as to cover a connection part of the power wiring layer 3 to the circuit body 1 and the external terminals 2. The filling member 12 is an insulating material such as a resin, and is filled, so that the circuit body 1 and the external terminal 2 are insulated, and the power wiring layer 3 and a cooler 7 are insulated. The filled state of the filling member 12 (existence/non-existence of bubbles, filling factor, and the like) can be easily confirmed from above the upper surface of the substrate 5 due to provision of the through hole 14. Accordingly, it is possible to improve reliability of the filled result of the filling member 12.

A heat conduction member 13 is disposed below the conductive member 9, and an insulating member 6 is disposed therebelow. The insulating member 6 is formed of a ceramic substrate or an insulating resin sheet, and is fixed to the cooler 7 by such process as brazing and crimping. The insulating member 6 has its upper part in contact with the heat dissipation member 4, the filling member 12, and the heat conduction member 13. The heat dissipation member 4 is in contact with the power wiring layer 3 at the lower side of the substrate 5. That is, the heat dissipation member 4 is disposed between the substrate 5 and the cooler 7. The power wiring layer 3 is in contact with the cooler 7 via the heat dissipation member 4 and the insulating member 6. This allows the power wiring layer 3 to dissipate heat to a refrigerant 8 flowing to the inside of the cooler 7 so that the temperature of the substrate 5 is lowered.

As the heat conduction member 13 the heat dissipation grease which has high thermal conductivity and is capable of suppressing the contact thermal resistance. The heat dissipation member 4 is formed of a resin sheet having high thermal conductivity and elasticity (flexibility) capable of following the stepped part and warp of the substrate 5.

The insulating member 6 is disposed between the cooler 7 and the circuit body 1, and between the cooler 7 and the substrate 5, so that the cooler 7 and the circuit body 1 are insulated from each other and the cooler 7 and the substrate 5 are insulated from each other. The heat dissipation member 4 is formed above the cooler 7 to allow improvement in the effect for cooling the circuit body 1 via the filling member 12 filled in an inner region (region enclosed by the frame part 4a).

The region enclosed by the heat dissipation member 4 formed with the frame part 4a on the insulating member 6 of the bottom surface is tightly filled with the filling member 12 from the through hole 14 as described above. The filling member 12 is fully filled so as to enclose the outer periphery of the region where the circuit body 1 is mounted. This allows the filling member 12 to serve as the potting mold of the circuit body 1, thereby to securely insulate the circuit body 1 from the substrate 5 and the power wiring layer 3 while preventing the outflow of the insulating coating material (filling member 12). This makes it possible to fill the filling member 12 with low viscosity, which makes the filling process easier than the generally employed process. The use of the low viscosity filling member allows bubbles generated in the filling member 12 to be easily removed, and by suppressing mixing of the bubbles, it is possible to enhance insulation reliability of the semiconductor module 100.

The filling member 12 is filled into the inner peripheral side of the frame part 4a formed by the sheet-shaped heat dissipation member 4. This may reduce the required insulation distance between the external terminals 2 each having a different potential and protruding from the circuit body 1 in the same direction. It is therefore possible to bring those external terminals 2 into adjacent to each other. The circuit body 1 and the substrate integrated type semiconductor module 100 can be made compact as a whole.

It is necessary to secure the width between the two external terminals 2 protruding from the circuit body 1 in the same direction to approximately 3 mm to 4 mm, for example, on the ground that the voltage is high, and the external terminals 2 for different voltage signals have to be insulated. However, the region enclosed by the heat dissipation member 4 according to the present invention is tightly filled with the filling member 12. This makes it possible to keep the insulation distance constant even if the width between the two terminals is further reduced, thereby contributing to size reduction.

The cooler 7 is disposed as a cooler for the circuit body 1 and the substrate 5, and cools the circuit body 1 and the substrate 5 via the heat conduction member 13, the heat dissipation member 4, or the insulating member 6. The cooler 7 is formed of a material with excellent thermal conductivity such as aluminum and copper. In the cooler 7, fins and pins are provided on the surface which is in contact with the refrigerant 8. Accordingly, it is possible to increase the surface area in contact with the refrigerant 8 so that the cooling performance of the cooler 7 can be improved. The refrigerant 8 is a liquid such as cooling water, is externally pressure fed by a not shown pump to a flow passage of the cooler 7 from outside, and flows through an inner flow passage of the cooler 7.

The external terminal 2 and the power wiring layer 3 are disposed while being partially in contact with each other (FIG. 3). The above arrangement is made for the reason as described below. When manufacturing the actual circuit, the width of the power wiring layer 3 of the substrate 5 varies depending on the amount of current to be applied, and the circuit body 1 may be remotely disposed depending on the place. It is therefore necessary to improve the freedom on the arrangement of the circuit body 1. The power wiring layer 3 is made to have a partially thinned portion to form a stepped part. This allows examination of the solution for preventing displacement of components in a part in contact with the external terminal 2 while having its layer kept unchanged. Upon arrangement, the circuit body 1 (external terminal 2) and the substrate 5 may be vertically dislocated from each other according to convenience for design.

### First Modified Example

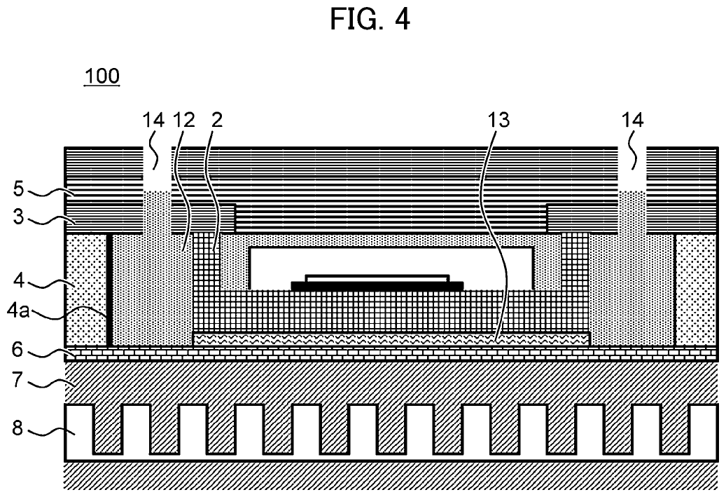

### (FIG. 4)

The substrate 5 with the through hole 14 is shaped to serve as a lid of the circuit body 1 when the substrate 5 is disposed to have its part covering the circuit body 1. The through hole 14 is formed at the inner peripheral side of the frame part 4a formed by the heat dissipation member 4. The filling amount of the filling member 12 can be easily adjusted, thereby to improve reliability of attaining the appropriate filling amount of the filling member 12. Further, provision of multiple through holes 14 increases the filling speed, and bubble removal can be easily performed.

### Second Modified Example

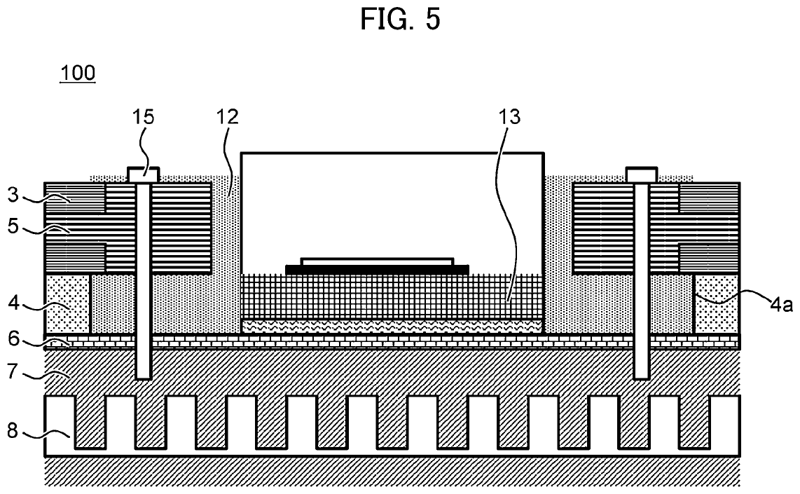

### (FIG. 5)

A fixing member 15 fixes the substrate 5 to the cooler 7 by means of a fixing hole in the substrate 5 and a fixing hole in the cooler 7, which are formed to pass the fixing member 15. A bolt or a screw may be used as the fixing member 15. The fixing member 15 is disposed at the inner peripheral side of the frame part 4a formed by the heat dissipation member 4. The fixing member 15 is disposed near the heat dissipation member 4, to thereby allow improvement in adhesiveness between the substrate 5 and the heat dissipation member 4, and between the insulating member 6 and the heat dissipation member 4. This makes it possible to suppress the outflow of the filling member 12. Further, the through hole 14 formed by the fixing member 15 in the insulating member 6 is filled with the filling member 12. The cooler 7 and the substrate 5 are insulated from each other, and the cooler 7 and the circuit body 1 are insulated from each other.

### Third Modified Example

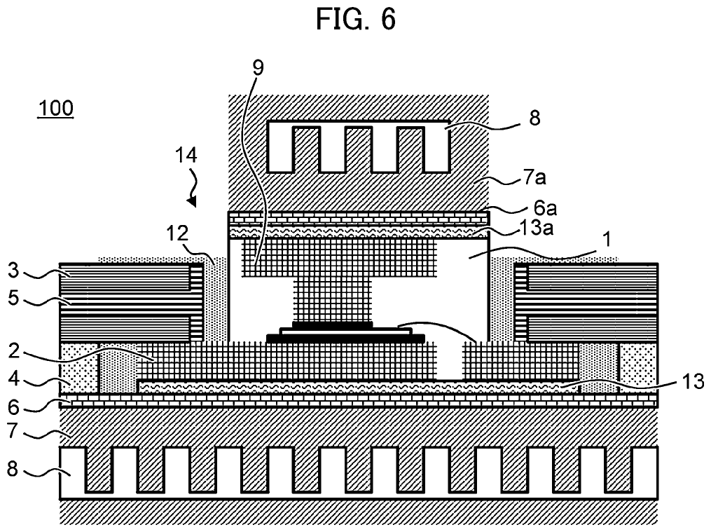

### (FIG. 6)

The cooler 7 is disposed at not only a lower surface but also an upper surface of the circuit body 1, to thereby cool both surfaces of the semiconductor element 10 of the circuit body 1. The cooler disposed at the upper surface side is referred to as a cooler 7a. A second insulating member 6a which is in contact with the cooler 7a is formed of a ceramic substrate or an insulating resin sheet, and fixed to the second cooler 7a by such process as brazing and crimping. The second insulating member 6a is disposed between the second cooler 7a and the circuit body 1, and between the second cooler 7a and the substrate 5 so that the second cooler 7a and the circuit body 1 are insulated from each other, and the second cooler 7a and the substrate 5 are insulated from each other. As the second heat conduction member 13a, a heat dissipation grease which exhibits high thermal conductivity and allows suppression of the contact thermal resistance is used. The second heat conduction member 13a is arranged between the circuit body 1 and the second insulating member 6a. The second cooler 7a is disposed at the position that is not overlapped with the through hole 14 of the substrate 5, which is filled with the filling member 12.

As a result, since the circuit body 1 is cooled also from the upper surface, the temperature of the semiconductor element in the circuit body 1 is prevented from rising, resulting in improved reliability of the circuit body 1. The filling member 12 can be filled in the state where the cooler 7 and the second cooler 7a are assembled to the substrate 5 and the circuit body 1, respectively. This makes it possible to visually confirm the filled state of the filling member 12.

An embodiment of the present invention as described above provides the following advantageous effects.

(1) The semiconductor module 100 includes: the circuit body 1 having the semiconductor element 10 and the plurality of external terminals 2 to be connected to the semiconductor element 10; the substrate 5 having the power wiring layer 3 to be connected to the external terminals 2; the insulating filling member 12 for covering the connection part between the external terminals 2 and the power wiring layer 3; the cooler 7 having one surface side on which the circuit body 1 and the substrate 5 are mounted; and the heat dissipation member 4 disposed between the cooler 7 and the substrate 5. The heat dissipation member 4 forms a frame part 4a on the cooler 7 so as to enclose the outer periphery of the region where the circuit body 1 is mounted, and the filling member 4 is filled into the inner peripheral side of the frame part 4a. This allows the semiconductor module 100 to attain both improvement in the cooling performance of the substrate 5, and high density of the terminal wiring.
(2) The substrate 5 has the through hole 14 through which the filling member 12 is filled into the inner peripheral side of the frame part 4a. This makes it possible to improve reliability of the filled state of the filling member 12.
(3) The circuit body 1 is disposed at an inner side of the through hole 14 formed in the substrate. The filling member 12 to be filled into the through hole 14 allows the circuit body 1 and the surrounding electrical components to be insulated from one another, and protected from the foreign substance.
(4) A part of the substrate 5 is disposed so as to cover the circuit body 1. As a result, the substrate 5 is shaped to serve as the lid to the circuit body 1. This allows the filling member 12 to be easily filled from the through hole 14 arranged at the remaining part of the substrate 5, resulting in improved reliability of the filled result.
(5) The fixing member 15 for fixing the substrate 5 and the cooler 7 to each other is provided, and the fixing member 15 is disposed at the inner peripheral side of the frame part 4a. Accordingly, it is possible to improve adhesiveness between the substrate 5 and the heat dissipation member 4, and adhesiveness between the insulating member 6 and the heat dissipation member 4. This makes it possible to suppress the outflow of the filling member 12. Further, the through hole 14 in the insulating member 6 generated (formed) by the fixing member 15 is filled with the filling member 12, to thereby insulate the cooler 7 and the substrate 5 from each other, and insulate the cooler 7 and the circuit body 1 from each other.
(6) The second cooler 7a is provided on the upper surface of the circuit body 1, and the second cooler 7a is disposed at the position that is not overlapped with the through hole 14 of the substrate 5, which is filled with the filling member 12. As a result, the circuit body 1 is also cooled from the upper surface to further suppress the temperature rise of the semiconductor element in the circuit body 1, resulting in improved reliability of the circuit body 1. The filling member 12 can be filled in the state where the cooler 7 and the second cooler 7a are assembled to the substrate 5 and the circuit body 1, respectively. This makes it possible to visually confirm the filled state of the filling member 12.

The present invention is not limited to the embodiment as described above. Various modifications and other structures may be combined in the range without deviating from the scope of the invention. The present invention is not limited to the one provided with all structures which have been described with respect to the above-described embodiment, and also includes the partially omitted structure.

### REFERENCE SIGNS LIST

1: circuit body
2: external terminal
3: power wiring layer
4: heat dissipation member
4a: frame part
5: substrate
6: insulating member
6a: second insulating member
7: cooler
7a: second cooler
8: refrigerant
9: conductive member
10: semiconductor element
11: sealing resin
12: filling member
13: heat conduction member
13a: second heat conduction member
14: through hole
15: fixing member
100: substrate integrated type semiconductor module

1. A semiconductor module comprising:
a circuit body having a semiconductor element, and a plurality of external terminals to be connected to the semiconductor element;
a substrate having a power wiring layer to be connected to the external terminals;
an insulating filling member for covering a connection part between the external terminals and the power wiring layer;
a cooler having one surface side on which the circuit body and the substrate are mounted; and
a heat dissipation member disposed between the cooler and the substrate, wherein
the heat dissipation member forms a frame part on the cooler so as to enclose an outer periphery of a region where the circuit body is mounted, and
the filling member is filled into an inner peripheral side of the frame part.

2. The semiconductor module according to claim 1, wherein
the substrate has a through hole through which the filling member is filled into the inner peripheral side of the frame part.

3. The semiconductor module according to claim 2, wherein
the circuit body is disposed at an inner side of the through hole formed in the substrate.

4. The semiconductor module according to claim 3, wherein
a part of the substrate is disposed so as to cover the circuit body.

5. The semiconductor module according to claim 1, further comprising a fixing member for fixing the substrate and the cooler to each other, wherein
the fixing member is disposed at the inner peripheral side of the frame part.

6. The semiconductor module according to claim 1, further comprising a second cooler on an upper surface of the circuit body, wherein
the second cooler is disposed at a position that is not overlapped with the through hole of the substrate, which is filled with the filling member.
